(19) United States
(12) Patent Application Publication
(10) Pub. No.: US 2013/0077416 A1
(43) Pub. Date: Mar. 28, 2013

(54) Memory device and method of performing a read operation within a memory device

(71) Applicant: Betina Hold, El Dorado Hills, CA (US)

(72) Inventor: Betina Hold, El Dorado Hills, CA (US)

(73) Assignee: ARM LIMITED, Cambridge (GB)

(21) Appl. No.: 13/200,400

(22) Filed: Sep. 23, 2011

(51) Int. Cl. G11C 7/12; G11C 7/00

(52) U.S. Cl. 365/189.15

(57) ABSTRACT

A memory device includes an array of memory cells arranged in rows and columns, each memory cell being configured to connect to separate write and read paths. The memory cells within each column form a plurality of memory cell groups and are coupled to the read data output circuitry by an associated read path. For each column, the associated read path comprises both a local path portion provided for each memory cell group and a global path portion shared by all memory cells within the column. The global path portion is then connected to the read data output circuitry. Each local path portion is coupled to an associated global path control circuit which is configured during the read operation to control a signal level of the associated global path portion in dependence on a signal level present on the associated local path portion.

### BACKGROUND OF THE INVENTION

1. Field of the Invention

The present invention relates to a memory device, and a method of performing a read operation within such a memory device.

2. Description of the Prior Art

As process geometries shrink in modern data processing systems, the variability in the operating characteristics of the individual circuit elements increases. Considering as an example a memory device consisting of an array of memory cells, it will be understood that each memory cell will typically consist of a number of electronic components such as transistors, and the variability in those individual components significantly increases as process geometries shrink. Furthermore, there is an increasing desire to operate data processing systems at lower and lower supply voltages, and as the supply voltage decreases, reliability issues due to the variations in the individual components become more prominent.

Given this trend, it has been realised that the standard known 6T (six transistor) SRAM memory cells do not provide sufficient stability for use in such modern data processing systems. Accordingly, much research has been undertaken to develop alternative forms of SRAM memory cells that can provide better operating characteristics when used in modern data processing systems. Some examples of work in this area are discussed in the following papers:

the paper by M. Margala, entitled “Low-power SRAM circuit design,” in Proceedings of the IEEE International Workshop on Memory Technology, Design, and Testing, August 1999, pp. 115-122;

the paper by J Kulkarni et al, entitled “A 160 mV Robust Schmitt Trigger Based Subthreshold SRAM”, in IEEE Journal of Solid-State Circuits, Vol 42, No. 10, October 2007, pp. 2303-2313;

the paper by I. Carlson et al, entitled “A high density, low leakage, 5T SRAM for embedded caches,” in Proceedings of the 30th European Solid State Circuits Conference (ESSCIRC), September 2004, pp. 215-218;

the paper by R. Aly et al, entitled “Novel 7T SRAM ell for low power cache design,” in Proceedings of the IEEE SOC Conference, 2005, pp. 171-174;

the paper by L. Chang et al, entitled “Stable SRAM Cell Design for the 32 nm Node and Beyond,” published in Symposium on VLSI Technology Digest, 2005, pp. 128-129; and

the paper by P. Liu et al, entitled “A Dual Core Oxide 8T SRAM Cell with Low Vccmin and Dual Voltage Supplies in 45 nm Triple Gate Oxide and Multi Vt CMOS for Very High Performance yet Low Leakage Mobile SoC Applications”, Symposium on VLSI Technology Digest, 2010, pp 135-136.

One particular form of memory cell that has received much attention in recent times is the 8T SRAM memory cell. One significant benefit of an 8T SRAM memory cell, in addition to its improved stability when compared with a 6T SRAM memory cell, is that it is possible to perform overlapped write and read operations, due to the presence of separate write and read access paths. This enables significant performance improvements when performing certain operations, for example read-modify-write operations. In addition, when compared with the known 6T SRAM memory cell, an 8T SRAM memory cell will often be able to operate with a lower minimum operating voltage, thereby enabling energy consumption savings to be realised within a memory device.

However, one significant problem with the 8T SRAM memory cell is that significant leakage current may be drawn by the memory cell. In particular, the provision of the dedicated read path in addition to the existing write access path provides another path between the supply voltage and ground, thereby increasing the overall leakage current. The earlier-mentioned paper entitled “A Dual Core Oxide 8T SRAM Cell with Low Vccmin and Dual Voltage Supplies in 45 nm Triple Gate Oxide and Multi Vt CMOS for Very High Performance yet Low Leakage Mobile SoC Applications”, discusses this leakage problem and seeks to alleviate it through the use of different oxide devices which exhibit different threshold voltages. In particular, thick core oxide transistors are used for the transistors that latch the data value and for the write transistors receiving the write word line. However, the transistors used in the read access path continue to use thin core oxide transistors, since the use of thick core oxide transistors would have too much of a detrimental effect on the read access speed. Accordingly, significant leakage current can still be drawn through the read access path.

Accordingly, it would be desirable to provide a design of SRAM memory cell which enabled the benefits of an 8T SRAM memory cell to be achieved, but with less overhead and with less leakage current than would typically be observed by an 8T SRAM memory cell.

### SUMMARY OF THE INVENTION

Viewed from a first aspect, the present invention provides a memory device comprising: an array of memory cells arranged in rows and columns, each memory cell being configured to connect to separate write and read paths; read data output circuitry configured, during a read operation, to output from the memory device read data received from a number of addressed memory cells within a selected row; the memory cells within each column of memory cells forming a plurality of memory cell groups, and being coupled to said read data output circuitry by an associated read path; for each column, the associated read path comprising a local path portion provided for each memory cell group, and a global path portion shared by all memory cells within the column, the global path portion being coupled to the read data output circuitry; each local path portion being coupled to an associated global path control circuit, each global path control circuit being configured during the read operation to control a signal level of the associated global path portion in dependence on a signal level of the associated local path portion; and each memory cell including a local path control circuit configured, when that memory cell is one of said addressed memory cells for the read operation, to control the signal level on the associated local path portion in dependence on the data value stored in that memory cell.

By logically separating each column into a series of memory cell groups, providing a local path portion for each memory cell group, and a separate global path portion shared between all of the memory cells in a particular column, a read path can be constructed which exhibits significantly less leakage current than in a typical 8T SRAM memory cell.

Each memory cell includes a local path control circuit that, during the read operation, controls the signal level on the associated local path portion in dependence on the data value stored in that memory cell. In addition, the local path portion is coupled to the global path portion via a global path control circuit, and each global path control circuit controls a signal level of the associated global path portion in dependence on the signal level present on the associated local path portion. Since multiple memory cells share the same local path portion, the number of potential leakage paths created by the read access path can be significantly reduced when compared with the standard 8T SRAM cell arrangement. Furthermore, when not performing a read operation, each global path control circuit can effectively isolate the memory cells from the global path portion, thereby removing that potential leakage path.

In addition, due to the component that couples the local path portion to the global path portion (i.e. the global path control circuit) being shared between all memory cells of a memory cell group, it has been found that a memory device constructed in accordance with the techniques of the present invention can be made smaller than the equivalent memory device constructed using 8T SRAM memory cells.

The global path control circuit can take a variety of forms. However, in one embodiment the global path control circuit comprises an amplifier circuit, such that any transition in the signal on the coupled local path portion is amplified in order to bring about a change in the signal on the global path portion.

In one particular embodiment, the global path control circuit comprises a transistor whose gate is coupled to the local path portion, and whose source and drain provide a path between the global path portion and a reference voltage level. Since this transistor is shared by all of the memory cells within the associated memory cell group, it will be appreciated that the cost of providing this transistor is amortized across all of those memory cells in the memory cell group, thereby resulting in a space efficient design.

The local path control circuit can take a variety of forms, but in one embodiment comprises a transistor connected between a storage node of the memory cell and the associated local path portion. The transistor can be used in a variety of configurations, and hence for example in one embodiment may have its gate connected to the storage node, whilst in another embodiment may have its source connected to the storage node. In one embodiment, the transistor forming the local path control circuit is an NMOS transistor, but in alternative embodiments a PMOS transistor can be used.

The memory cells used in accordance with the present invention can take a variety of forms. However, in one particular embodiment, each memory cell comprises seven transistors, one of said transistors forming the local path control circuit connected between a storage node of the memory cell and the associated local path portion. Thus, when comparing this design with a known 8T SRAM arrangement, it will be seen that each memory cell has one less transistor. An additional transistor is used to form the global path control circuit, but that transistor is associated with all the memory cells of the memory cell group, and accordingly, as mentioned earlier, its cost is amortized across the memory cells of that memory cell group.

If we hence consider an example where each memory cell group contains eight memory cells, then it can be seen that if the global path control circuit is taken into account when determining the transistor count for a memory cell, the transistor count for each memory cell is 7.125T due to the cost of the global path control circuit transistor being amortized across eight memory cells. Hence, by such an approach, the size of the memory device can be reduced, whilst still retaining the read and write stability, read and write ease and performance benefits, and low operating minimum voltage benefits of an 8T SRAM memory cell. Furthermore, when compared with a typical 8T SRAM memory cell, the memory device constructed in accordance with the above described embodiments exhibits less leakage current.

In one embodiment, the memory device further comprises: precharge circuitry configured to precharge each local path portion to a first predetermined voltage level prior to said read operation being performed; and the local path control circuit of each addressed memory cell then being configured to selectively drive the voltage on its associated local path portion towards a second predetermined voltage level dependent on the data value stored at a storage node of the memory cell. The choice of the first and second predetermined voltage levels will be dependent on the implementation, and in particular will be dependent on how the local path control circuit is configured and driven within the memory cells.

In one embodiment, each global path control circuit is responsive to the voltage on the associated local path portion transitioning towards said second predetermined voltage level during the read operation to drive the voltage on said global path portion towards a reference voltage level. Accordingly, whenever the voltage level on a local path portion changes during the read operation, this causes the voltage on the associated global path portion to transition towards a reference voltage level. When the global path portion voltage is subsequently evaluated, a determination as to whether the global path portion voltage has transitioned towards said reference voltage is used to sense the stored data value in the associated addressed memory cell.

In one embodiment, the precharge circuitry is further configured to precharge each global path portion to a global precharge voltage level different to said reference voltage level prior to said read operation being performed.

Accordingly, it will be understood that during the read operation, the voltage on the global path portion will either remain at the global precharge voltage, or will be driven towards the reference voltage, dependent on the value stored within the addressed memory cell connected to the corresponding column. The voltage on the global path portion can then be evaluated following a predetermined read timing window in order to detect the value stored within the addressed memory cell.

In one embodiment, a multiplexing functionality can be provided within the memory device to allow a selection to be made between memory cells in different columns. In particular, in one embodiment, the memory device further comprises a first read activating path coupled to the local path control circuits of the memory cells in a first subset of the columns of the array, and a second read activating path coupled to the local path control circuits of the memory cells in a second subset of the columns of the array. For at least some read operations, only one of the first read activating path and the second read activating path are used, such that the addressed memory cells reside within only one of the first subset of the columns and the second subset of the columns. By such an approach, a discharge (due to the read operation) is required for only a subset of the columns (e.g. every alternate column in one embodiment) when performing the read operation, thereby reducing source current.

The first and second read activating paths can take a variety of forms. However, in one embodiment, the first read activating path comprises a first read word line for each row of the array, and the second read activating path comprises a second read word line for each row of the array.

Whilst the above-described multiplexing approach can be used in one embodiment to reduce source current, in another embodiment it can be used in addition, or alternatively, to reduce area of the memory device. In particular, in one embodiment, each local path portion is shared between at least one memory cell group in the first subset of the columns of the array and at least one memory cell group in the second subset of the columns of the array. Such a configuration is a useful way of reducing the area of the memory device, since the width is metal limited, and such an arrangement can significantly reduce the number of metal lines required.

Viewed from a second aspect, the present invention provides a method of performing a read operation within a memory device comprising an array of memory cells arranged in rows and columns, each memory cell being configured to connect to separate write and read paths, the method comprising: forming the memory cells within each column of memory cells into a plurality of memory cell groups; coupling each column to read data output circuitry by an associated read path, for each column, the associated read path comprising a local path portion provided for each memory cell group, and a global path portion shared by all memory cells within the column; coupling the global path portion to the read data output circuitry; coupling each local path portion to an associated global path control circuit, and during the read operation using each global path control circuit to control a signal level of the associated global path portion in dependence on a signal level of the associated local path portion; providing a local path control circuit within each memory cell; and when one of said memory cells is an addressed memory cell for the read operation, using the local path control circuit of that memory cell to control the signal level on the associated local path portion in dependence on the data value stored in that memory cell.

Viewed from a third aspect, the present invention provides a memory device comprising: an array of memory cell means arranged in rows and columns, each memory cell means for connecting to separate write and read paths; read data output means for outputting from the memory device, during a read operation, read data received from a number of addressed memory cell means within a selected row; the memory, cell means within each column of memory cell means forming a plurality of memory cell groups, and being coupled to said read data output means by an associated read path means; for each column, the associated read path means comprising a local path portion means for each memory cell group, and a global path portion means for sharing by all memory cell means within the column, the global path portion means for coupling to the read data output means; each local path portion means for coupling to an associated global path control means, each global path control means for controlling, during the read operation, a signal level of the associated global path portion means in dependence on a signal level of the associated local path portion means; and each memory cell means including a local path control means for controlling, when that memory cell means is one of said addressed memory cell means for the read operation, the signal level on the associated local path portion means in dependence on the data value stored in that memory cell means.

### BRIEF DESCRIPTION OF THE DRAWINGS

The present invention will be described further, by way of example only, with reference to embodiments thereof as illustrated in the accompanying drawings, in which:

FIG. 1 is a diagram illustrating a known 8T SRAM memory cell design;

FIG. 2 is a diagram schematically illustrating a memory device in accordance with one embodiment;

FIG. 3 is a flow diagram illustrating the steps performed to implement a read operation in accordance with one embodiment;

FIGS. 4A, 4B, 5A, 5B, 6A and 6B illustrate memory cells and the associated read path provided within a column of a memory array in accordance with alternative embodiments; and

FIGS. 7A and 7B illustrate embodiments using read multiplexing techniques.

### DESCRIPTION OF EMBODIMENTS

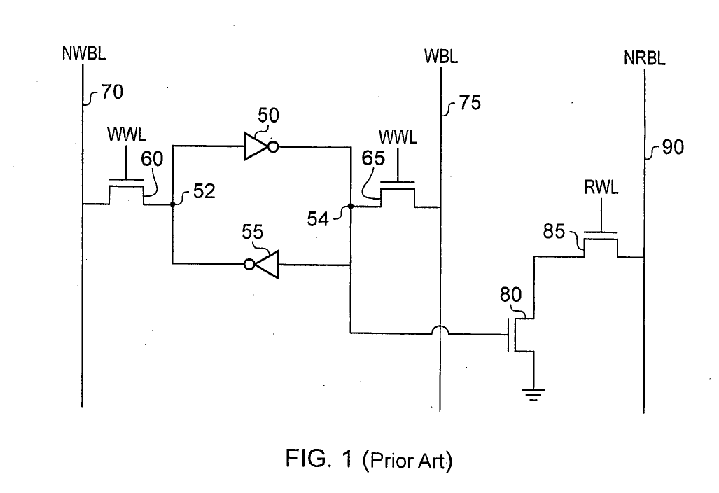

Prior to discussing the memory cells used within the memory device in accordance with embodiments of the present invention, the construction of a standard 8T SRAM cell will first be described with reference to FIG. 1.

As shown in FIG. 1, a latch formed of the two inverters 50, 55 (the two inverters are typically constructed using four transistors) is used to store a single bit data value. In particular, during a write operation, one of the write bit lines 70, 75 will be driven to a logic one value whilst the other write bit line will be driven to a logic zero value, since it has been precharged. At the same time, a write word line pulse will be provided to the driver transistors 60, 65 to turn those transistors on and thereby connect the write bit lines to the latch. This will cause the nodes 52, 54 to be driven to opposite logic levels to thereby encode either a logic zero value or a logic one value within the latch. At the end of the write operation, the pulse provided to the drive transistor 60, 65 will be de-asserted, whereafter the written value will be retained within the latch.

In addition, a series of transistors 80, 85 is connected to a read bit line 90. When it is desired to read the cell, a read word line pulse is provided to the transistor 85 to turn that transistor on. At this point, the read bit line 90 will typically have been precharged to a logic one value and will now be placed into a floating condition. As a result, that read bit line will either remain at the logic one level or start to discharge, dependent on whether the transistor 80 is turned on, this in turn depending on the value stored within the latch formed by the inverters 50, 55. This read operation can be performed simultaneously with the write operation, and at the end of the read operation, the value of the bit line 90 can be assessed in order to determine what value is stored within the bit cell.

Whilst such a cell has been found to provide good stability whilst allowing the cell to have a relatively low minimum operating voltage, it can exhibit significant leakage current. In particular, in addition to the leakage paths presented by the write bit lines 70, 75, the separate read path from the node 54 through the transistors 80, 85 and the read bit line 90 provides an additional leakage path. Furthermore, when a logic one value is stored at the node 54, it will be appreciated that the transistor 80 is turned on, and in that event there is only a single transistor in the form of transistor 85 separating that node from a path to ground (when the bit line 90 is not in its precharged logic one state). In addition, such an 8T SRAM cell is significantly larger than the standard 6T SRAM cell, and for example may be up to 1.8 times larger, thereby having an adverse effect on the size of the memory.

Embodiments of the present invention provide a memory cell arrangement which retains the benefits of the 8T SRAM memory cell, but with reduced leakage current.

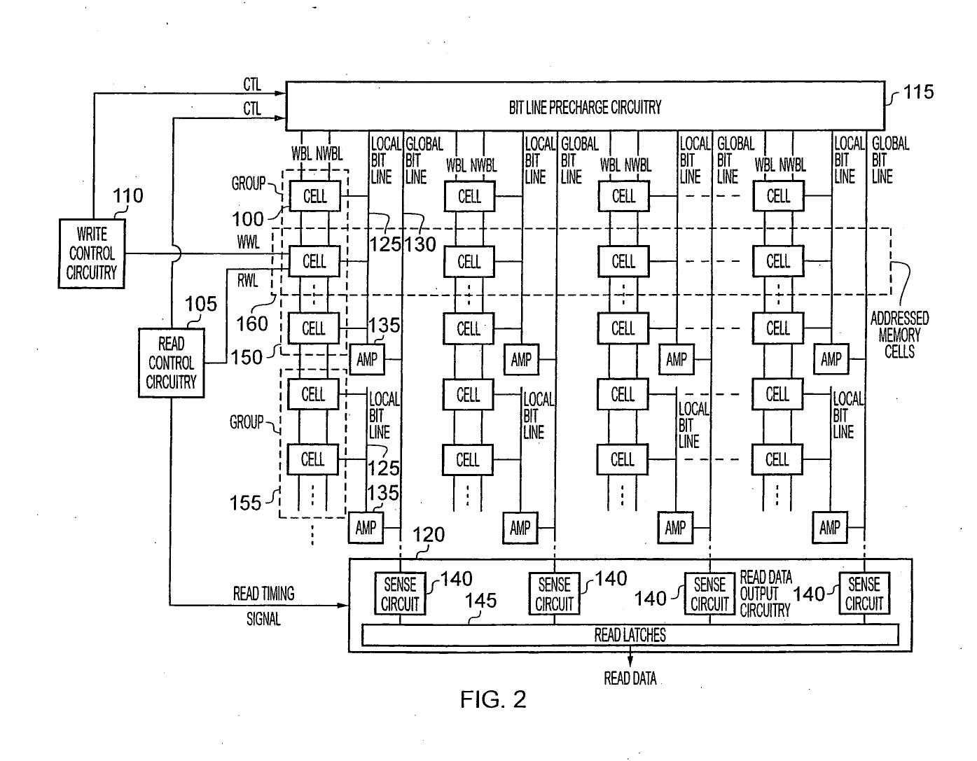

FIG. 2 is a block diagram of a memory device in accordance with embodiments of the present invention. An array of memory cells 100 are provided, and each column of memory cells is considered to consist of a number of logical groups 150, 155. Each of the cells is configured to connect to separate write and read paths, the write path being formed by the write bit lines WBL and NWBL just like the earlier-described 8T SRAM cell, whilst the read path is formed by a combination of a local bit line and a global bit line. In particular, each of the memory cells 100 within a particular group shares a local bit line, and accordingly the memory cells within the group 150 are connected to the local bit line 125, the memory cells within the group 155 are connected to another local bit line 125, etc.

Each local bit line 125 is coupled to an associated global bit line 130 via an amplifier circuit 135 (also referred to herein as a global path control circuit).

Bit line precharge circuitry 115 is provided for precharging the write bit lines and read bit lines prior to write and read operations. Write operations are controlled in a standard way by write control circuitry 110, which will issue appropriate control signals to the bit line precharge circuitry 115, and will also be responsible for issuing the write word line signals to activate the addressed memory cells within a particular row of the memory array. The write operation will proceed in the same way as described for the 8T SRAM cell, and accordingly the bit line precharge circuitry 115 will be responsible for driving the two write bit lines associated with each addressed memory cell to the appropriate logic one and logic zero values in order to ensure that when the write word line signal is asserted, the correct value is stored within each addressed memory cell.

Read control circuitry 105 controls read operations, and accordingly will send appropriate control signals to the bit line precharge circuitry 115 to cause the local bit line and global bit line for each column containing an addressed memory cell to be precharged to appropriate precharge voltages prior to the read operation beginning A read word line signal will then be asserted to the addressed memory cells (in this example it being assumed that the addressed memory cells are those within the row 160). When the read word line is asserted to an addressed memory cell, the voltage on the coupled local bit line will either remain at its precharged voltage level, or transition towards another voltage level, dependent on the value stored within the cell. Assuming the precharged voltage level does not change, then the associated amplifier circuitry 135 will not be activated, and the global bit line 130 will also remain at its precharged voltage level. However, assuming the voltage level on the local bit line changes, then the amplifier 135 will be activated to cause the voltage on the global bit line 130 to be transitioned towards a reference voltage.

Following a read timing window sufficient to ensure that the stored state within each addressed memory cell has had time to affect both the voltage on the local bit line and the global bit line, the read control circuitry 105 will assert a read timing signal to the read data output circuitry 120, which will cause each of the sense circuits 140 to sample the voltage on the connected global bit line 130. The sample data values will then be stored within the read latches 145 for output as the read data.

The memory cells 100 can take a variety of forms, but in one embodiment each include a single transistor for coupling a storage node of the memory cell to the associated local bit line. The amplifier 135 can also typically be formed of a single transistor, or a transistor and associated inverter, dependent on embodiment. The cost of the amplifier circuit 135 is amortized across all of the memory cells within the relevant memory cell group. Such an arrangement can lead to an overall reduction in the number of transistors used when compared with the standard 8T SRAM cell discussed earlier. For example, in one embodiment each of the memory cells 100 has a standard six transistor (6T) arrangement to form the two latches and the two driver transistors connected to the write word lines WBL and NWBL. An additional transistor is then provided for coupling a storage node of the cell to the local bit line, and accordingly each of the cells 100 has seven transistors. In embodiments where the amplifier circuitry 135 is also formed of a single transistor, then it can be seen that the number of transistors per memory cell will be less than eight, since the transistor forming the amplifier 135 is amortized across the memory cells of each memory cell group. In a particular example, if each memory cell group contains eight memory cells, then there are 7.125 transistors (7.1251) per memory cell.

In addition to reducing the transistor count, the arrangement shown in FIG. 2 also exhibits reduced leakage current in association with the read access path when compared with the standard 8T SRAM arrangement. In particular, when a read operation is not being performed, each of the amplifier circuits 135 effectively isolates the memory cells from the global path portion, and hence removes a potential leakage path. Furthermore, since a plurality of memory cells all share the same local bit line, the number of potential leakage paths is in any event reduced when compared with a standard 8T SRAM cell arrangement.

It will be understood that FIG. 2 is purely a schematic illustration of the memory device, and the exact placement of individual components within the memory device will vary dependent on implementation. By way of example, although the bit line precharge circuitry 115 is shown at the top of the memory array, in one embodiment it will be provided at the bottom of the memory array along with the read data output circuitry 120.

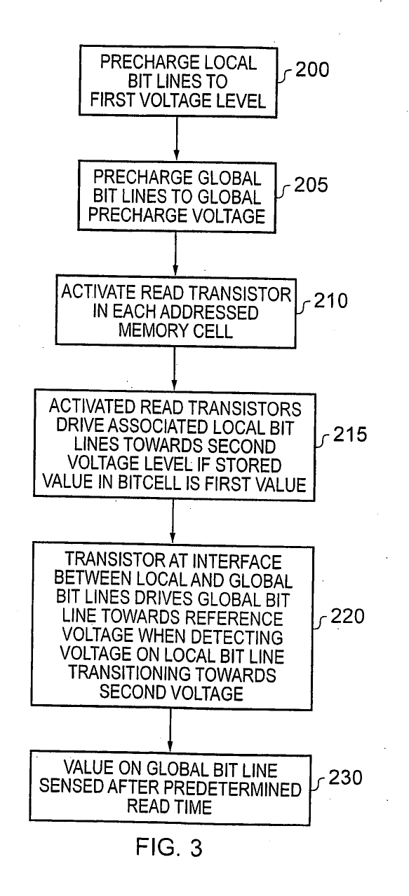

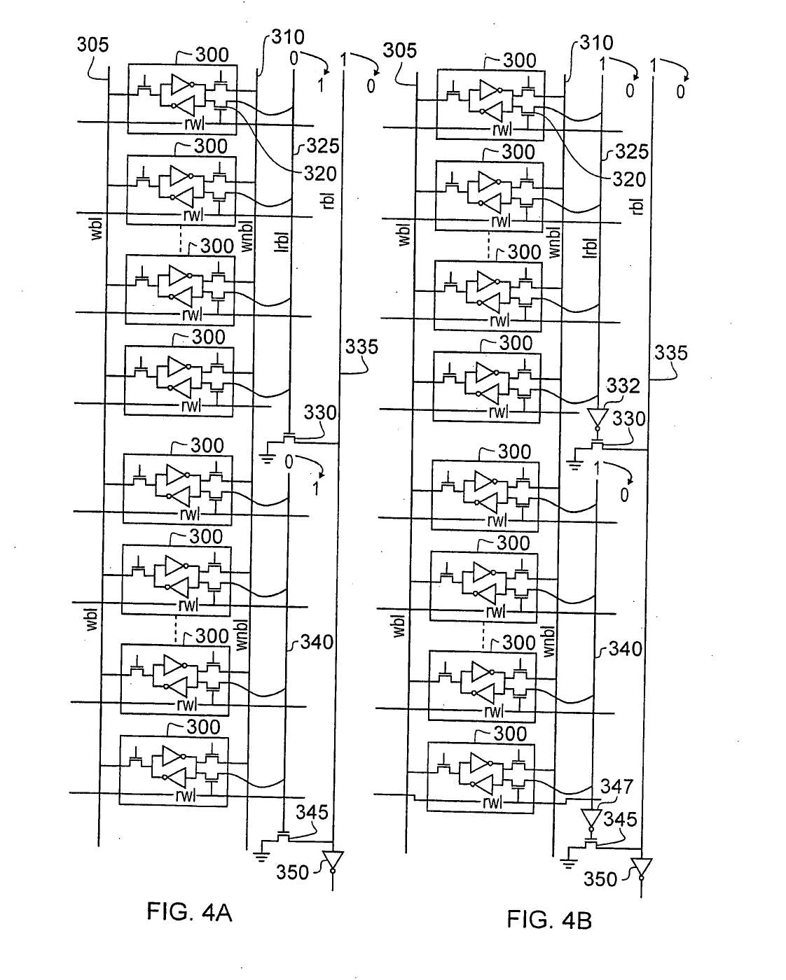

FIG. 3 is a flow diagram illustrating the steps performed in order to implement a read operation in accordance with one embodiment. At step 200, the bit line precharge circuitry 115 is used to precharge the local bit lines to a first voltage level. The choice of first voltage level will depend on embodiment, and a number of different embodiments will be discussed later with reference to FIGS. 4A to 6B.

At step 205, the global bit lines are precharged to a global precharge voltage, and again the choice of the global precharge voltage will be dependent on the particular embodiment.

Following the precharge operations, the read transistor in each addressed memory cell is activated at step 210, the read transistor being the transistor that couples the storage node of the addressed memory cell with the associated local bit line. As indicated at step 215, once the read transistors have been activated, they will drive the associated local bit lines towards a second voltage level if the stored value in the bit cell is a first value, or alternatively the precharge voltage on the local bit line will be retained if the stored value in the bit cell is a second value. The first and second values will depend on the embodiment, as will be apparent from the particular examples discussed later with reference to FIGS. 4A to 6B.

At step 220, the transistor forming the amplifier circuit 135 at the interface between the local bit line and an associated global bit line will drive the global bit line towards a reference voltage when it detects a voltage on the local bit line transitioning towards the second voltage level. Hence, if the voltage on the local bit line changes during the read operation, this will activate the amplifier 135 to cause it to drive the global bit line towards the reference voltage level.

At step 230, following the read timing window, the sense circuits 140 will sense the value on each global bit line and that value will be used to generate a value stored within the relevant read latch 145.

FIG. 4A illustrates a particular formation of memory cell that may be used in accordance with one embodiment, along with a corresponding form of amplifier circuit 135. In particular FIG. 4A shows a portion of a column of the memory array, this portion consisting of a plurality of memory cells 300 forming two memory cell groups with a non-specified number of memory cells per group (the number of memory cells in each group is a matter of design choice). The first memory cell group is connected to a local bit line 325 which in turn is connected via an NMOS transistor 330 (forming the amplifier circuit 135) to the global bit line 335. Similarly, the second memory cell group is connected to the local bit line 340 which is turn is coupled via the transistor 345 to the global bit line 335. In this embodiment, the sense circuit 140 of FIG. 2 is formed by the inverter 350 which acts as an amplifier to generate a signal for latching within the relevant read latch 145. As also shown in FIG. 4A, each of the memory cells is connected to a pair of write bit lines 305, 310.

In addition to the standard six transistors used to form the two latches and the driver transistors used in the write operation, each memory cell 300 also includes an NMOS read transistor 320 which has its source connected to a storage node of the memory cell and its drain connected to the local bit line. In addition, its gate is connected to the read word line. This transistor forms a local path control circuit.

In the example illustrated in FIG. 4A, the local bit lines 325, 340 are precharged to a logic zero level, and the global bit line 335 is precharged to a logic one level. When the read word line is activated at a logic one level, this will turn the read transistor 320 on in each addressed memory cell. As a result, if the storage node connected to the read transistor stores a logic zero value, no change will occur on the local bit line, and accordingly no change will occur on the global bit line. However, if the storage node connected to the read transistor 320 is at a logic one level, this will cause the local bit line 325 to be pulled towards the logic one level. In one embodiment the logic one level used to activate the read word line may represent a nominal voltage, say Vdd, but in an alternative embodiment a boosted voltage may be provided (say Vdd+Vt) to cause the read transistor 320 to be driven more strongly, and hence cause the local bit line 325 to transition towards the local one level more quickly if the storage node connected to the read transistor 320 is at a logic one level.

When the local bit line 325 is pulled towards the logic one level, then once the threshold voltage of the transistor 330 has been overcome, this will cause the transistor 330 to turn on, which in turn will draw the voltage on the global bit line 335 towards the logic zero level. Once the voltage on the global bit line has dropped to a certain level, this will cause the output from the inverter 350 to flip state (i.e. the output will change to a logic one level) and that output can then be stored within the relevant read latch.

FIG. 4B illustrates exactly the same arrangement of memory cell 300, again the read transistor 320 having its source connected to the storage node and its gate connected to the read word line. However, in this example, the local bit line is precharged to a logic one level. As before, the global bit line is precharged to a logic one level. An inverter 332, 347 is then inserted prior to each transistor 330, 345, respectively. As a result, in this embodiment, a logic one value at the storage node coupled to the read transistor will cause no change in the voltage on the local and global bit lines, but a logic zero value stored at the storage node will cause the voltage on the local bit line to transition towards a logic zero level when the read word line is asserted. Due to the inverter 332, this will cause the transistor 330 to be turned on once the voltage on the local bit line has dropped sufficiently to overcome the threshold voltage of the transistor 330. Once the transistor 330 is turned on, then in the same way as described earlier with reference to FIG. 4A, this will cause the voltage on the global bit line 335 to be pulled towards the reference voltage (in the example of FIGS. 4A and 4B the reference voltage being ground), and accordingly this will cause the inverter 350 to flip its output state in the same way as described earlier for FIG. 4A.

One benefit of the approach of FIG. 4B is that no boosted read word line voltage is necessary, but the design does require a larger amplifier to couple the local bit lines to the global bit lines (when compared to the design of FIG. 4A), whose cost needs to be amortized over several rows of the memory.

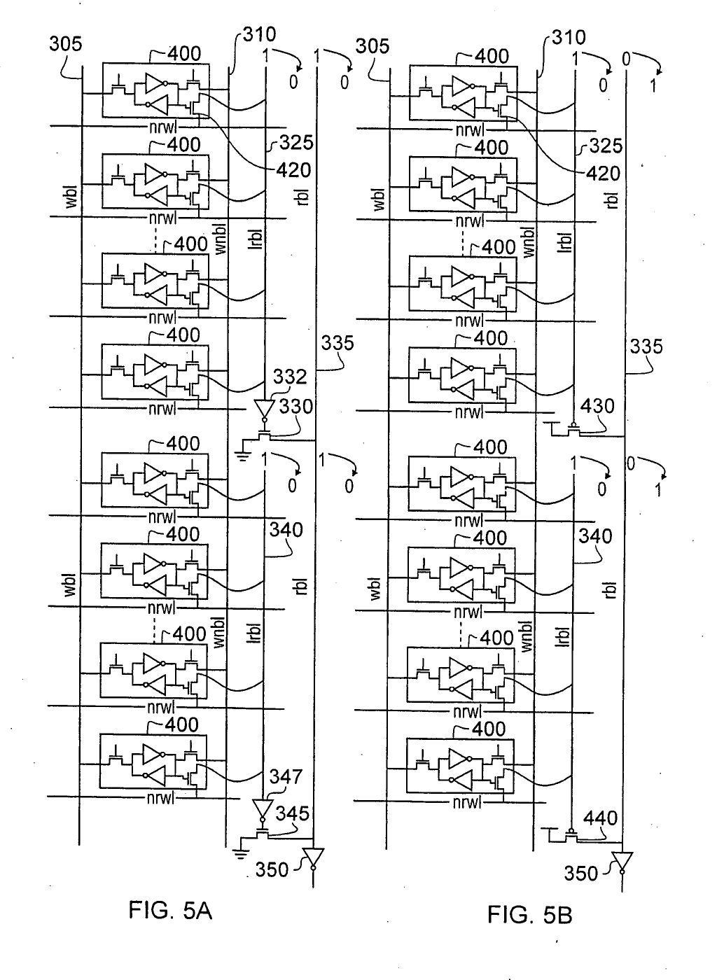

FIG. 5A illustrates an alternative form of memory cell 400 where the read transistor 420 has its gate connected to the storage node and its source connected to an inverted version of the read word line. By arranging the gate of the read transistor to be connected to the storage node, the gate loading of the read circuitry can be used to reduce the current loading on the bit cell. The read word line has three states, namely a logic zero state, a logic one state or a floating state.

The local bit lines, global bit lines and associated amplifier circuits have the same arrangement as in FIG. 4B, and as with FIG. 4B both the local bit lines and the global bit lines are precharged to the logic one level. When the read word line is asserted, the inverted version of the read word line will go to a logic zero level. Accordingly, if a logic one value is retained at the storage node coupled to the gate of the read transistor 420, the read transistor will be turned on, and accordingly will pull the voltage on the local bit line towards the ground voltage, thereby turning on the transistor 330 via the inverter 332, and accordingly causing the voltage on the global bit line to transition towards the logic zero level. In one embodiment, the inverters 332, 347 have their behaviour skewed dependent on whether a logic one value or a logic zero value is being read.

FIG. 5B uses the same arrangement of memory cell 400 as shown in FIG. 5A, but on this occasion a PMOS transistor 430 is used to form the amplifier 135 connecting each local bit line 325, 340 to the global bit line 335. In addition, the global bit line is in this embodiment precharged to a logic zero level. As with FIG. 5A, a logic one value held at the storage node coupled to the gate of the read transistor 420 will turn the transistor 420 on, and accordingly when the read word line is asserted this will cause the voltage on the local bit line 325 to transition towards a logic zero level, thereby turning on the PMOS transistor 430. In this example, the reference voltage is Vdd, and accordingly when the transistor 430 is turned on, this will cause the voltage on the global bit line 335 to be pulled up from the logic zero level towards the logic one level, at some point this causing the output from the inverter 350 to flip state so as to output a logic zero value. Whilst the output from the inverter 350 is in the embodiment of FIG. 5B of opposite state to the logic value held at the storage node within the memory cell, this can be taken into account when determining what value to store within the read latches 145.

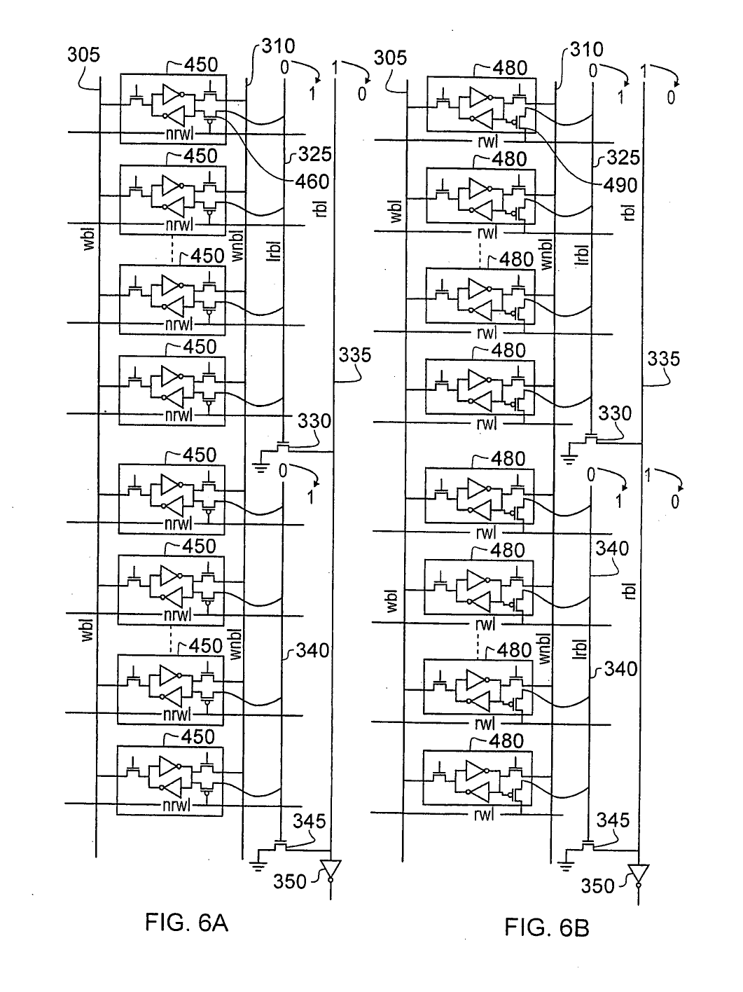

In the examples of FIGS. 4A, 4B, 5A and 5B the read transistors are formed by NMOS transistors. However, FIGS. 6A and 6B illustrate a couple of alternative embodiments where PMOS transistors are used to form the read transistors. Whilst four separate figures could be shown to reflect the equivalence of the four possible options shown in FIGS. 4A, 4B, 5A and 5B, two examples are shown purely for the sake of illustration.

In the example of FIG. 6A, each memory cell 450 includes a PMOS read transistor 460 whose source is connected to the storage node and whose gate is connected to an inverted version of the read word line. The local bit lines 325, 340 are precharged to a logic zero level and the global bit line 335 is precharged to a logic one level. When a logic one value is held at the storage node connected to the read transistor, it will be seen that when the read word line is asserted, the PMOS read transistor 460 will turn on, and begin to drive the local bit line 325 towards the logic one level. This will subsequently cause the transistor 330 to turn on and draw the voltage on the global bit line 335 towards the logic zero level. FIG. 6A can hence be seen to illustrate a PMOS embodiment equivalent to the NMOS embodiment of FIG. 4A.

Since PMOS transistors are better passers of a logic 1 value than a logic 0 value (due to no loss of threshold voltage), they can provide a more optimal solution in certain embodiments, when compared with NMOS transistors which are better passers of a logic 0 value than a logic 1 value.

FIG. 6B illustrates a memory cell 480 which includes a PMOS read transistor 490, in this example the PMOS transistor 490 having its gate connected to the storage node and its source connected to the read word line. As with the example of FIG. 6A, the local bit lines 325, 340 are precharged to the logic zero level and the global bit line 335 is precharged to the logic one level. When the read word line is asserted, then if a logic zero value is stored at the storage node coupled to the gate of the read transistor 490, the read transistor will be turned on and will pull the voltage on the local bit line towards the logic one level. At some point, this will turn on the transistor 330, thereby drawing the voltage on the global bit line 335 towards the logic zero level. FIG. 6B can hence be considered to provide a PMOS memory cell equivalent to the NMOS memory cell of FIG. 5A, the difference being that a logic zero value held at the storage node in FIG. 6B causes a transition of the voltages on the bit lines, whereas in FIG. 5A it was a logic one value held at the storage node which caused such transitions to occur.

In all of the examples shown in FIGS. 4A to 6B, the inverter 350 could be replaced with a single ended sense amp if desired.

The above described embodiments illustrate the flexibility of the approach of the present invention. In contrast to known 8T memory cell arrangements, the described embodiments use seven transistors within each memory cell, and allow the read transistor to be coupled so as to provide the local bit line with either a gate load or a source load. A source load arrangement will require more current drive, but will add an extra cascade stage which lowers the leakage current.

Further, the described technique allows a balance to be achieved between the number of rows connected to each local bit line (i.e. the size of each memory cell group) and the number/size of the amplifier circuits required to couple local bit lines to global bit lines. Hence, any particular implementation can be optimized having regard to the amplifier size and the size of the memory cell groups to achieve a desired balance between size and leakage current reduction.

The above described embodiments provide an efficient bit cell array which offers a lower minimum operating voltage, read and write stability, and read and write ease and performance improvements over a traditional 6T SRAM memory cell. Whilst at 8T SRAM memory cell also offers such advantages, it does so at an area cost and a leakage cost. However, the above described embodiments can reduce the area cost when compared with an 8T SRAM cell. Furthermore, the embodiments described above provide a reduction in leakage current when compared with typical 8T SRAM cell arrangements.

Furthermore, the hierarchical arrangement of the read access paths, consisting of a local bit line shared by the memory cells of a memory cell group, coupled, by an amplifier circuit to a global bit line, can provide a reduced disturbance on the bit cell caused by read bit line perturbations due to the hierarchical nature of the architecture. The hierarchical arrangement also provides less capacitive loading for the discharge process when such a small bitcell current is being: generated. This will decrease the sense time of the small differential signal and can lead to performance improvements.

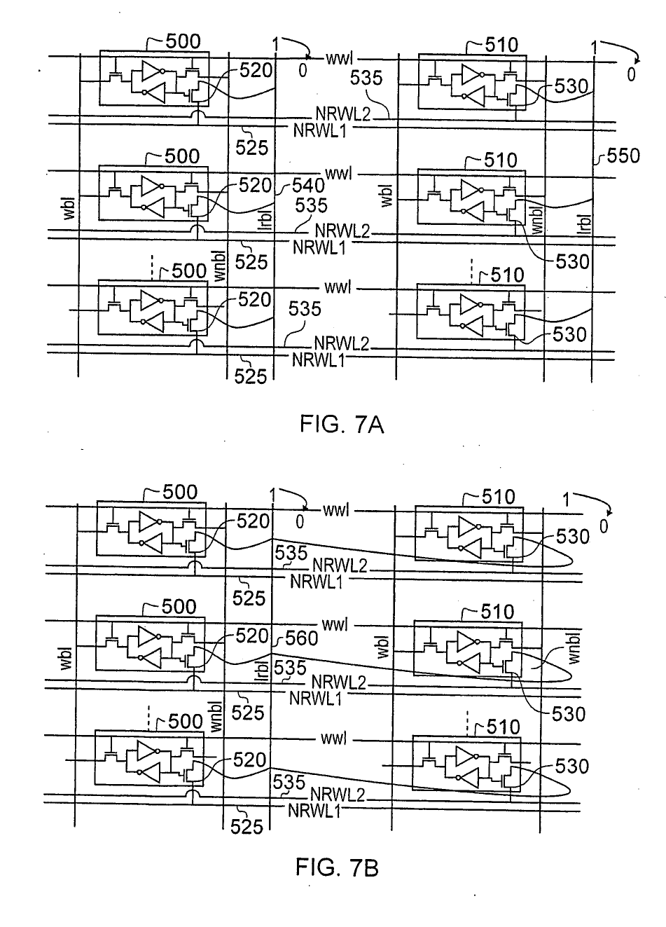

In one embodiment, a multiplexing functionality can be provided if there is space to fit an extra read word line into the horizontal pitch. By such an arrangement, a selection can be made between two bitcells in a pair of columns of bitcells, thereby allowing a discharge to be performed every alternate column when performing the read operation, thereby saving on source current. As a particular example, a read multiplexer could be used to reduce the nrwl (source line) current when the nrwl solution is used, as illustrated in FIG. 7A. In FIG. 7A, one memory cell group in each of two adjacent columns are shown, each memory cell group being shown connected to an associated local bit line. However, for ease of illustration, the global bit lines, and the components used to couple the local bit lines to the global bit lines, are omitted. In the example of FIG. 7A, the memory cells have the form discussed earlier with reference to the examples of FIGS. 5A and 5B. The memory cells 500 associated with the first column have their read transistors 520 coupled to a first source line 525, whilst the memory cells 510 associated with the adjacent column have their read transistors 530 coupled to a second source line 535. A read multiplexer can be used to drive either the first source line 525 or the second source line 535 for any particular read operation, thereby causing only a subset of the columns to be addressed in a particular read operation, and hence the current consumption to be reduced (typically by at least one half).

As another example a read multiplexer can be used to share a bitline over the shared NMOS diffusion. Such an arrangement is shown in FIG. 7B, where again one memory cell group in each of two adjacent columns are shown. The memory cells have the same construction as shown in FIG. 7A, but in the example of FIG. 7B the two adjacent columns share a single local bit line 560. Such a configuration is a useful way of reducing the area of the memory device, since the width is metal limited, and such an arrangement can significantly reduce the number of metal lines required.

Although particular embodiments have been described herein, it will be appreciated that the invention is not limited thereto and that many modifications and additions thereto may be made within the scope of the invention. For example, various combinations of the features of the following dependent claims could be made with the features of the independent claims without departing from the scope of the present invention.

I claim:

1. A memory device comprising:
an array of memory cells arranged in rows and columns, each memory cell being configured to connect to separate write and read paths;
read data output circuitry configured, during a read operation, to output from the memory device read data received from a number of addressed memory cells within a selected row;
the memory cells within each column of memory cells forming a plurality of memory cell groups, and being coupled to said read data output circuitry by an associated read path;
for each column, the associated read path comprising a local path portion provided for each memory cell group, and a global path portion shared by all memory cells within the column, the global path portion being coupled to the read data output circuitry;
each local path portion being coupled to an associated global path control circuit, each global path control circuit being configured during the read operation to control a signal level of the associated global path portion in dependence on a signal level of the associated local path portion; and
each memory cell including a local path control circuit configured, when that memory cell is one of said addressed memory cells for the read operation, to control the signal level on the associated local path portion in dependence on the data value stored in that memory cell.

2. A memory device as claimed in claim 1, wherein said global path control circuit comprises an amplifier circuit.

3. A memory device as claimed in claim 2, wherein said global path control circuit comprises a transistor whose gate is coupled to the local path portion, and whose source and drain provide a path between the global path portion and a reference voltage level.

4. A memory device as claimed in claim 1, wherein the local path control circuit comprises a transistor connected between a storage node of the memory cell and the associated local path portion.

5. A memory device as claimed in claim 1, wherein each memory cell comprises seven transistors, one of said transistors forming the local path control circuit connected between a storage node of the memory cell and the associated local path portion.

6. A memory device as claimed in claim 1, further comprising:
precharge circuitry configured to precharge each local path portion to a first predetermined voltage level prior to said read operation being performed; and
the local path control circuit of each addressed memory cell then being configured to selectively drive the voltage on its associated local path portion towards a second predetermined voltage level dependent on the data value stored at a storage node of the memory cell.

7. A memory device as claimed in claim 6, wherein each global path control circuit is responsive to the voltage on the associated local path portion transitioning towards said second predetermined voltage level during the read operation to drive the voltage on said global path portion towards a reference voltage level.

8. A memory device as claimed in claim 7, wherein said precharge circuitry is further configured to precharge each global path portion to a global precharge voltage level different to said reference voltage level prior to said read operation being performed.

9. A memory device as claimed in claim 1, further comprising:
a first read activating path coupled to the local path control circuits of the memory cells in a first subset of the columns of the array; and
a second read activating path coupled to the local path control circuits of the memory cells in a second subset of the columns of the array;
for at least some read operations, only one of the first read activating path and the second read activating path being used, such that the addressed memory cells reside within only one of the first subset of the columns and the second subset of the columns

10. A memory device as claimed in claim 9, wherein:
said first read activating path comprises a first read word line for each row of the array; and
said second read activating path comprises a second read word line for each row of the array.

11. A memory device as claimed in claim 9, wherein each local path portion is shared between at least one memory cell group in the first subset of the columns of the array and at least one memory cell group in the second subset of the columns of the array.

12. A method of performing a read operation within a memory device comprising an array of memory cells arranged in rows and columns, each memory cell being configured to connect to separate write and read paths, the method comprising:
forming the memory cells within each column of memory cells into a plurality of memory cell groups;
coupling each column to read data output circuitry by an associated read path, for each column, the associated read path comprising a local path portion provided for each memory cell group, and a global path portion shared by all memory cells within the column;
coupling the global path portion to the read data output circuitry;
coupling each local path portion to an associated global path control circuit, and during the read operation using each global path control circuit to control a signal level of the associated global path portion in dependence on a signal level of the associated local path portion;
providing a local path control circuit within each memory cell; and
when one of said memory cells is an addressed memory cell for the read operation; using the local path control circuit of that memory all to control the signal level on the associated local path portion in dependence on the data value stored in that memory cell.

13. A memory device comprising:
an array of memory cell means arranged in rows and columns, each memory cell means for connecting to separate write and read paths;
read data output means for outputting from the memory device, during a read operation, read data received from a number of addressed memory cell means within a selected row;
the memory cell means within each column of memory cell means forming a plurality of memory cell groups, and being coupled to said read data output means by an associated read path means;
for each column, the associated read path means comprising a local path portion means for each memory cell group, and a global path portion means for sharing by all memory cell means within the column, the global path portion means for coupling to the read data output means;
each local path portion means for coupling to an associated global path control means, each global path control means for controlling, during the read operation, a signal level of the associated global path portion means in dependence on a signal level of the associated local path portion means; and
each memory cell means including a local path control means for controlling, when that memory cell means is one of said addressed memory cell means for the read operation, the signal level on the associated local path portion means in dependence on the data value stored in that memory cell means.
